(19) United States
(12) Patent Application Publication
(10) Pub. No.: US 2011/0181664 A1
(43) Pub. Date: Jul. 28, 2011

(54) Forming Self-Aligned Nozzles

(75) Inventors: Mark Nepomnishy, San Jose, CA (US); Gregory De Brabander, San Jose, CA (US)

(73) Assignee: FUJIFILM CORPORATION, Tokyo (JP)

(21) Appl. No.: 12/695,062

(22) Filed: Jan. 27, 2010

(51) Int. Cl. B41J 2/16; H01L 21/306

(52) U.S. Cl. 347/47; 438/21; 257/E21.215

(57) ABSTRACT

A method of forming a nozzle plate of a fluid ejection device includes performing a first etch from a first side of a wafer to form a tapered region, forming an oxide layer in the tapered region such that a depth of the oxide layer on the tapered walls is greater than a depth of the oxide layer on the floor, performing a second etch from the first side to remove the oxide layer from the floor and a portion of the oxide layer from the tapered wall, and performing a third etch from the first side to form an outlet passage having a straight wall.

### TECHNICAL FIELD

This description relates to forming etched features in a semiconductor material.

### BACKGROUND

In some implementations of a fluid droplet ejection device, a substrate, such as a silicon substrate, includes a fluid pumping chamber, a descender, and a nozzle formed therein. Fluid droplets can be ejected from the nozzle onto a medium, such as in a printing operation. The nozzle is fluidly connected to the descender, which is fluidly connected to the fluid pumping chamber. The pumping chamber can be actuated by a transducer, such as a thermal or piezoelectric actuator. When actuated, the fluid flows out of the pumping chamber and a fluid droplet is ejected through the nozzle. The medium can be moved relative to the fluid ejection device. The ejection of a fluid droplet from a nozzle can be timed with the movement of the medium to place a fluid droplet at a desired location on the medium. Fluid ejection devices typically include multiple nozzles, and it is usually desirable to eject fluid droplets of uniform size with uniform speed and direction to provide uniform deposition of fluid droplets on the medium.

### SUMMARY

In general, in one aspect, a method of forming a nozzle plate of a fluid ejection device includes performing a first etch from a first side of a wafer to form a tapered region, forming an oxide layer in the tapered region, performing a second etch from the first side, and performing a third etch from the first side. The first etch is performed on a first surface of a layer of the wafer. The tapered region has a floor parallel to the first surface and a tapered wall between the floor and the first surface. The oxide layer is formed in the tapered region such that a depth of the oxide layer on the tapered wall is greater than a depth of the oxide layer on the floor. The depth of the oxide layer on the tapered wall and on the floor is measured in a direction perpendicular to the first surface. The second etch is performed to remove the oxide layer from the floor and to remove a first portion of the oxide layer from the tapered wall. The second etch leaves a second portion of the oxide layer on the tapered walls. The third etch is performed to form an outlet passage having a straight wall perpendicular to the first surface. The passage is aligned with the tapered region, and the straight wall intersects a bottom edge of the tapered wall.

This and other embodiments can include one or more of the following features. The layer can be a single crystal material. The tapered wall can be along a {111} plane, and the floor can be along a {100} plane. The single crystal material can be silicon. The depth of the oxide on the tapered wall can be greater than about 7500 Å, and the depth of the oxide on the floor can be less than about 5500 Å. Growing an oxide layer in the tapered region can further include growing the oxide layer such that a thickness of the oxide layer on the tapered wall is greater than a thickness of the oxide layer on the floor. The thickness of the grown thermal oxide layer on the tapered wall can be greater than about 5500 Å, and the thickness of the grown thermal oxide layer on the floor can be less than about 5500 Å. Forming the oxide layer can include growing the oxide using thermal oxidation. Forming the oxide layer can include depositing the oxide using chemical vapor deposition. Performing the first etch can include performing an anisotropic wet etch. Performing the second etch can include performing a dry etch. Performing the third etch can include performing an anisotropic dry etch. Performing the third etch can include etching to a buried oxide layer. Performing the third etch can include etching to a highly doped layer. The method can further include removing the second portion of the oxide layer on the tapered wall after performing the third etch.

In general, in another aspect, a fluid ejection device includes a substrate having a flow path formed therein and a nozzle plate having a nozzle formed therein. The nozzle includes a tapered region having a tapered wall, an outlet passage having a straight wall, and an oxide layer coating the tapered wall, but not the straight wall. The tapered wall is connected to a wall defining the flow path. The straight wall is connected to the tapered wall.

This and other embodiments can include one or more of the following features. The outlet passage can have a square cross-section. The outlet passage can have a rectangular cross-section. The substrate can include silicon. The oxide can include silicon oxide. The oxide layer can have a thickness that varies by less than 5%. The oxide layer can have a thickness of less than 3,000 Å.

Some implementations may include one or more of the following advantages. Single side processing can simplify the nozzle formation process. Etching a tapered region and an outlet passage of a nozzle from a single side of a semiconductor layer in a self-aligned manner can allow for improved alignment of the recess to the outlet passage. The improved alignment can reduce the need for registration marks (e.g., no registration marks are needed), and/or reduce the number of aligning masks required to fabricate the nozzle (e.g., only one mask level is required). Better alignment can result in a nozzle in which a central axis of the tapered region is substantially the same as or the same as a central axis of the outlet passage, which can allow the droplet to be ejected perpendicular to the nozzle plate surface. Because alignment is easier to achieve using this method, it can be easier to form an array of nozzles with aligned tapered region and outlet passages. Thus, nozzle-to-nozzle uniformity of nozzle shape and size can be improved, thereby providing a more consistent direction of droplet ejection nozzle-to-nozzle, improved uniformity of droplet deposition characteristics, and improved image quality.

The details of one or more implementations are set forth in the accompanying drawings and the description below. Other features, objects, and advantages will be apparent from the description and drawings, and from the claims.

### DESCRIPTION OF DRAWINGS

FIGS. 1-11 illustrate the steps of one implementation of a method of forming a nozzle plate and attaching it to a device layer.

Many of the layers and features are exaggerated to better show the process steps and results. Like reference symbols in the various drawings indicate like elements.

### DETAILED DESCRIPTION

Forming a nozzle plate for a fluid ejection device as described herein includes forming a number of nozzles each having a tapered region and an outlet passage. One difficulty in forming a nozzle with this shape is aligning the tapered region with the outlet passage, e.g., difficulty in fabricating a nozzle in which a central axis of the tapered region is substantially the same as or the same as a central axis of the outlet passage. Methods for performing the etch of the tapered region and the outlet passage from a single side of a layer are described that can reduce or eliminate the alignment problems encountered when the recessed section is etched from a side of the layer opposite to the outlet passage.

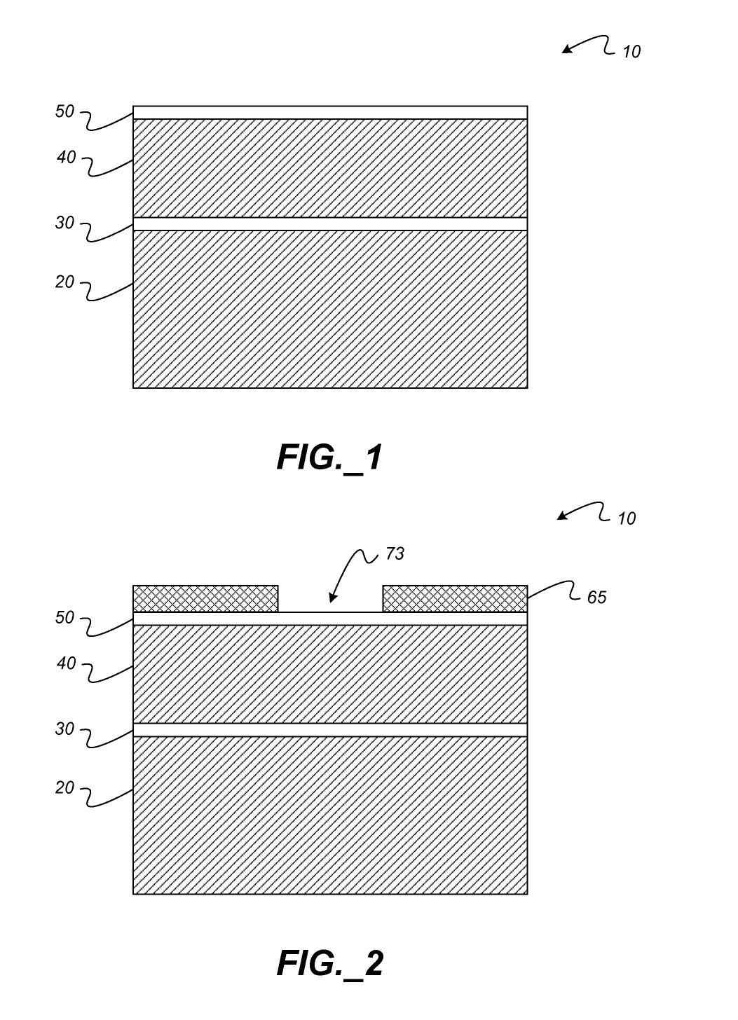

Referring to FIG. 1, a silicon-on-oxide (“SOI”) wafer 10 has a layer 40 of single crystal material, e.g., a silicon layer 40, a handle layer 20, and a buried oxide layer 30 between the silicon layer 40 and handle layer 20. The silicon layer 40 can have a <100> crystal orientation. The handle layer 20 can be formed of silicon. A second oxide layer 50 is on a side of the silicon layer 40 opposite to the handle layer 20. The second oxide layer 50 can be a thermal oxide grown on the silicon layer 40. Although the layers can have just about any thickness, the oxide layers 30, 50 are thinner than the silicon layer 40 and handle layer 20. In an exemplary SOI wafer 10, the oxide layers are less than a few microns thick, such as about 1 micron thick. The handle layer can have a thickness of greater than 200 microns, such as about 600 microns. The silicon layer 40 has the thickness of the final desired thickness of the nozzle plate. The silicon layer 40 can be at least 5 microns thick, and can be up to about 50 microns thick, e.g., the silicon layer 40 can be about 30 microns thick. In other implementations, the silicon layer 40 is about 50 microns thick. Only a portion of a wafer 10 is shown in the figures for the sake of simplicity. That is, the creation of a single nozzle is shown, but in most cases a plurality of nozzles will be formed simultaneously in the wafer 10.

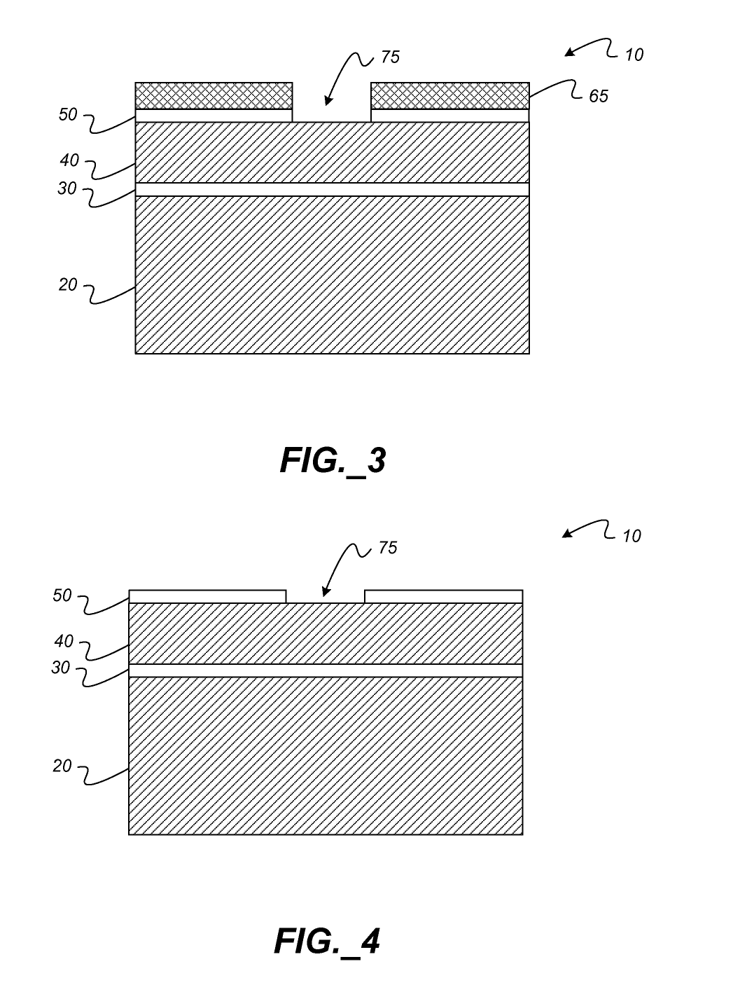

Referring to FIG. 2, a layer of photoresist 65 is applied to the oxide layer 50 that is over the silicon layer 40. The layer of photoresist 65 is patterned to create a square or rectangular aperture 73. The photoresist layer 65 with the aperture 73 is used as a mask for etching an aperture 75 into oxide layer 50, as shown in FIG. 3. The layer of photoresist 65 is then stripped from the wafer 10, as shown in FIG. 4.

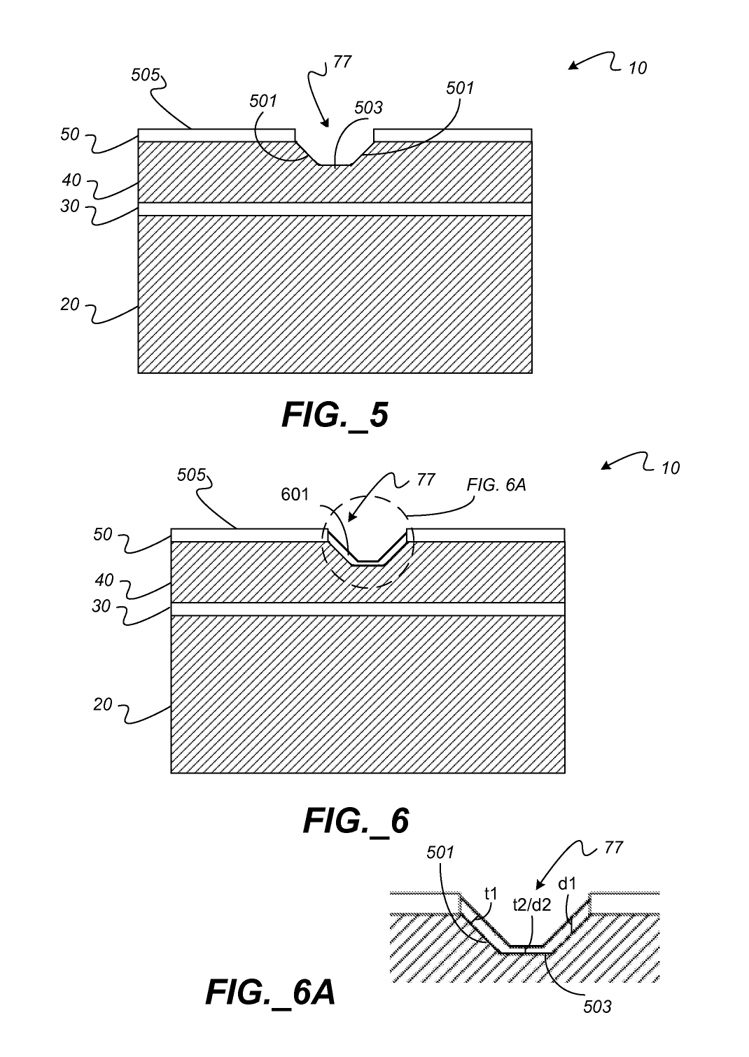

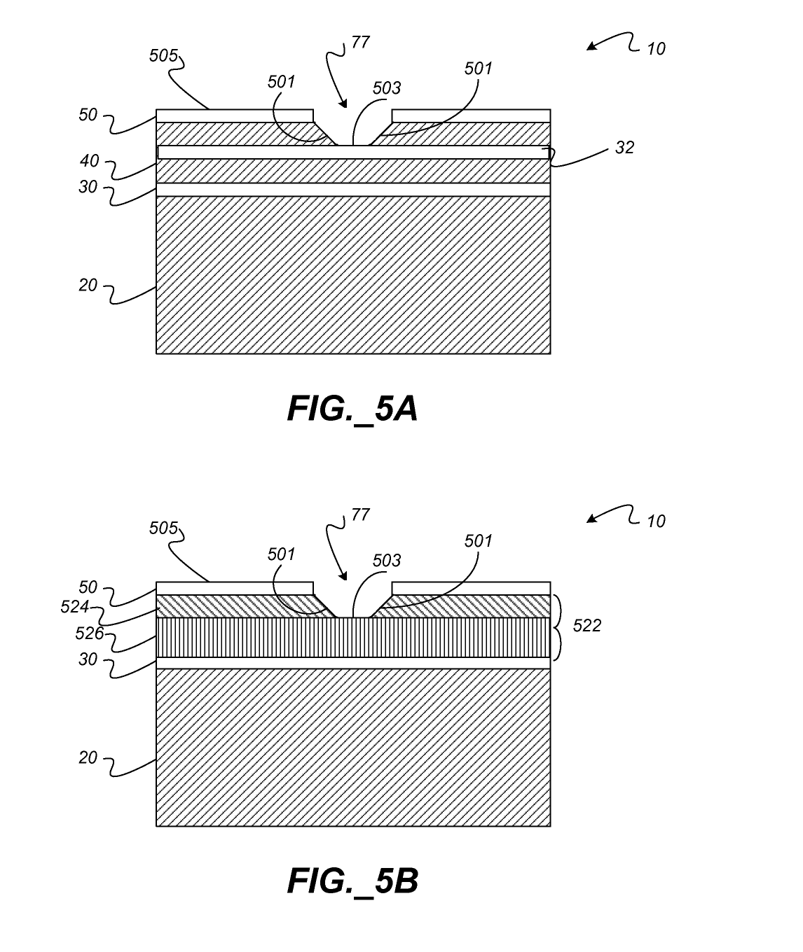

As shown in FIG. 5, an anisotropic etch, e.g., a wet etch, is then performed, using the remaining oxide from oxide layer 50 on top of silicon layer 40 as a mask. The anisotropic etch, for example, a tetramethylammonium hydroxide (TMAH) or potassium hydroxide (KOH) etch, stops on the {111} crystal plane to form angled or tapered sidewalls 501. This forms the tapered region 77 of the nozzle. The tapered region 77 can have a truncated pyramidal shape with tapered walls 501 along the {111} planes and a floor 503 along the {100} plane. The floor 503 can be parallel to the top surface 505 of the wafer 10. The tapered walls 501 can be tilted at an angle of 54.7° relative to the top surface 505. The wet etch can be stopped when the distance between the floor 503 and the buried oxide layer 30 is equal to the desired outlet passage length or the recess has the desired width. Thus, in some implementations, the wet etch can be timed to stop at the desired distance. In other implementations, shown in FIG. 5A, an additional buried oxide layer 32 can be present to act as an etch stop to the wet etch. In other implementations, the etch can proceed through an epitaxial layer, and a heavily doped layer can act as an etch stop. For example, as shown in FIG. 5B, an expitaxial layer 522 can include an N− layer 524 and a heavily doped layer 526, e.g. a P++ layer. In the implementation of FIG. 5B, the N− layer 524 is etched, e.g. with KOH or TMAH etch, and the heavily doped layer 526 acts as an etch stop.

As shown in FIG. 6, an oxide layer 601 is then grown on the tapered region 77. The oxide layer 601 can be grown using a wet thermal oxide process in which vaporized water is circulated over the recess 77. Optionally, water can also be circulated over the top surface 505 of the wafer 10, thereby simplifying the process and slightly increasing the thickness of the oxide layer 50 already present on the wafer 10. The wet thermal oxide process can occur at temperatures of between approximately 800° C. and 1200° C., such as 1000° C. to 1100° C., for example 1080° C. The wet thermal oxide process can take between ½ hour and 5 hours, such as between 1 and 2 hours, for example approximately 90 minutes. Alternatively, a dry thermal oxide process can be used. Because the oxide layer 601 is deposited thermally, a thickness of the oxide layers in a direction perpendicular to the wall surface on which it is formed can vary by less than 5%, such as less than 3%, over a distance of at least 5 μm. The density of the oxide layer can be greater than approximately 2.0 g/cm³, such as about 2.2 g/cm³.

The rate of growth of the thermal oxide, and thus the resulting final thickness, will depend on the orientation of the exposed surface. For example, for <111> silicon, the rate of growth on the {111} surfaces, measured in a direction perpendicular to the wall on which the oxide is growing, is approximately 10-15% higher than the rate of growth on the {100} surfaces. As a result, the thickness of the oxide layer on the {111} walls in the direction perpendicular to the respective {111} wall is greater than the thickness of the oxide layer on the {100} floor. Moreover, because the {111} walls are sloped, the difference in depth perpendicular to the top surface 505, i.e., in the in the [001] direction, between the oxide layers on {111} walls and the {100} floor is even greater. More generally, as measured perpendicular to the floor of the recess or the surface 505, the depth of the oxide layer on the tapered walls is greater than the depth of the oxide layer on floor.

Referring to FIG. 6A, the oxide formed on surfaces along the tapered walls 501 can have a first thickness t1, while the oxide formed on the floor 503 can have a second thickness t2. The thickness t1 of the thermal oxide deposited on the tapered walls 501 is greater than the thickness t2 of the thermal oxide deposited on the floor 503. For purposes of masking against etching, the oxide on the floor has a thickness t2 while that on the walls has a depth d1=t1/(cos 54.74°)=1.73 t1. Thus, the oxide masking depth on the walls 501 is greater than that on the floor 503 both because of higher growth rate and the tilt of the walls.

For example, the thickness t2 can be less than approximately 5500 Å, such as about 5000 Å, while the thickness t1 can be greater than approximately 5500 Å, such as about 6547 Å. Further, the oxide formed on the floor 503 can have a depth d2 (d2 and t2 are equivalent), while the oxide formed along the tapered walls 501 can have a depth d1, where the depths are measured in the [001] direction, i.e., perpendicular to the top surface 505 of the wafer 10. The depth d1 of the thermal oxide deposited on the tapered walls 501 is greater than the depth d2 of the thermal oxide deposited on the floor 503. For example, the depth d2 can be less than approximately 5500 Å, such as about 5000 Å, while the depth d1 can be greater than approximately 5500 Å, such as greater than 7500 Å or greater than 9600 Å, for example 9787 Å.

In some implementations, chemical vapor deposition (CVD) is used to create the oxide layer 601 rather than thermal oxidation. Unlike thermal oxidation, the rate of oxide deposition during CVD is equivalent along all exposed planes. As a result, the thickness of the oxide layer perpendicular to each wall is equal. However, due to the tilt of the taped {111} walls in the recess 77, the depth d1 of the portion of the oxide layer 601 along the tapered walls is still greater than the depth d2 of the {100} of the portion of the oxide layer 601 along the bottom {100} wall of the recess.

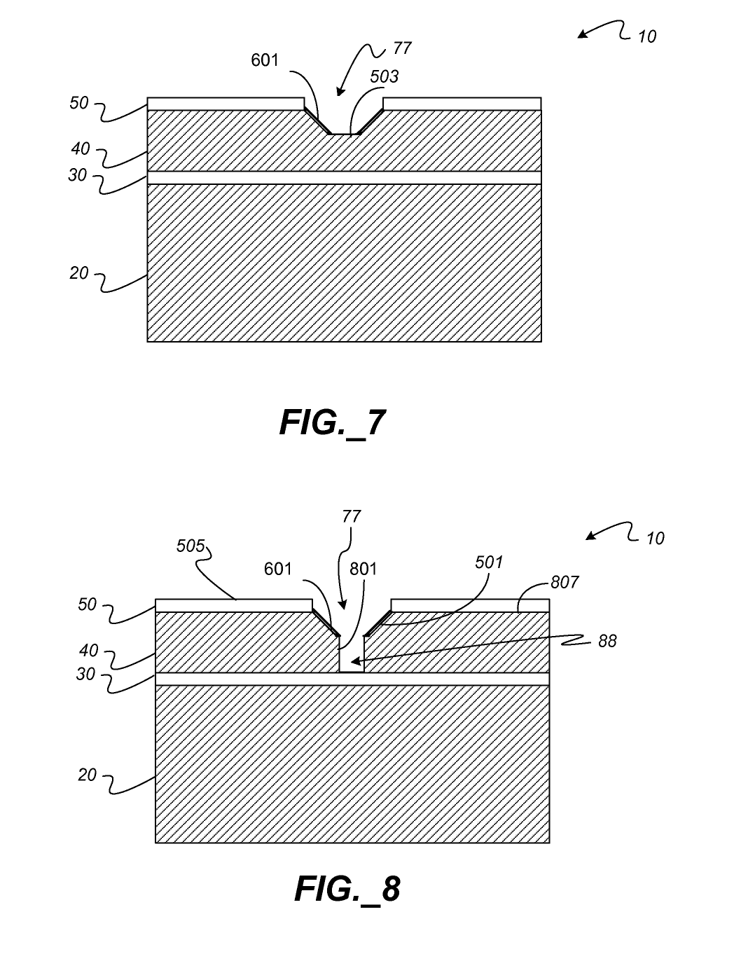

Referring to FIG. 7, a dry etch is performed on the oxide layer 601. In one implementation, an anisotropic etch, e.g., an oxide dry etch, such as a plasma etch, is performed. The etching is stopped once all of the oxide layer 601 has been removed from the {100} floor 503 of the recess 77. During the etch, the tapered walls 501 are not masked over. However, because the depth and/or thickness of the oxide layer is less along the {100} floor of the recess than along the {111} tapered walls 501, part of the oxide layer 601 remains on the tapered {111} walls after the oxide has been fully removed from the {100} floor 503 of the recess 77. In an alternate implementation, if a thickness of the oxide layer 601 on the tapered walls 501 is greater than a thickness of the oxide layer 601 on the floor 503, e.g., if the oxide layer 601 is a thermal oxide layer that, an isotropic etch can be performed on the oxide layer 601. Because the oxide layer 601 on the tapered walls 501 is thicker than on the floor 503, part of the oxide layer 601 remains on the tapered walls 501 after the oxide has been fully removed from the floor 503 of the recess 77.

The thickness of the oxide layer 601 remaining on the tapered walls 501 can be less than 3,000 Å, such as between 1,500 Å and 2,500 Å. As an example, a wet thermal oxide can be grown at 1000° C. for 1 hour to create the oxide layer 601. The thickness of the oxide layer on the floor, t2, will be 3,913 Å, while the thickness on the tapered walls, t1, will be 7,833 Å. After an anisotropic etch of the floor, including a 10% over-etch, the oxide layer on the floor will be completely removed, and the oxide thickness on the tapered walls, t1, will be 2,037 Å.

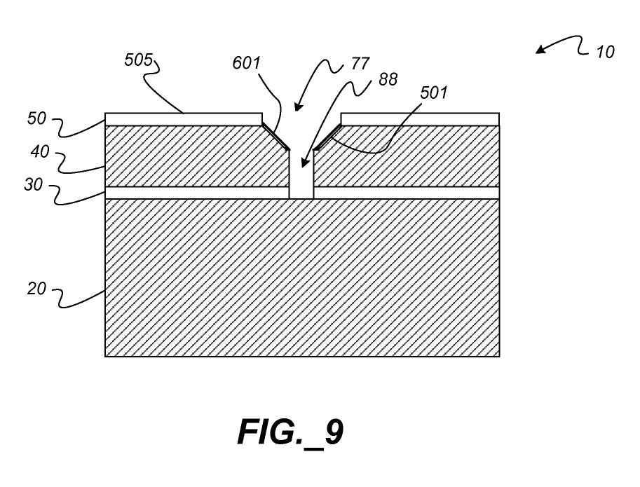

Referring to FIG. 8, a silicon anisotropic dry etch, such as a Bosch process, is used to etch the {100} floor 503. In the implementation shown in FIG. 8, the etch can etch through the silicon layer 40. In the implementation described with respect to FIG. 5A, the oxide layer 32 can be etched, and then the anisotropic dry etch can be used to etch through the silicon layer 40. Further, in the implementation described with respect to FIG. 5B, the etch can be performed through the highly doped layer 526. Etching through the floor 503 forms the outlet passage 88 of the nozzle. The oxide layer 50 and portion of the oxide layer 601 remaining are not masked during the etch. Rather, the oxide layer 50 and the portion of the oxide layer 601 remaining on the tapered {111} walls serves as a mask for the etch, so that the side walls of the outlet passage 88 are aligned with the bottom edge of the tapered walls 501. The outlet passage 88 can have substantially straight walls 801 extending from the recess 77 to the buried oxide layer 30. The straight walls 801 can extend along the {100} planes perpendicular to the surface 505 of the wafer 10 and can intersect with the tapered walls of the recess 77. Because the oxide layer 601 remains on the side of the tapered {111} walls, it acts as a mask so that the tapered {111} walls are not etched. Similarly, because the oxide layer 50 remains on the top surface, it acts as a mask so that the top surface 807 of the silicon layer 40 is not etched. The resulting outlet passage 88 will be self-aligned to the recess 77 and will have the same cross-section as the floor 503, e.g. a square or rectangle. The etching is stopped when it hits the buried silicon oxide layer 30. In some implementations, shown in FIG. 9, the buried oxide layer 30 is then etched through so as to leave the oxide material as a nozzle coating. In some implementations, the oxide layer 601 is removed from the {111} walls after the outlet passage 88 is formed.

Following the dry etch, the recess 77 and the outlet passage 88 can together be called a nozzle, and the wafer 10 can be termed a nozzle plate or a collection of nozzle plates if multiple nozzle plates are formed in a single wafer. The nozzle can be symmetric, i.e., can have an axis through a center of the recess 77 that is the same as an axis through a center of the outlet passage 88 to within 1% of the diameter of the nozzle.

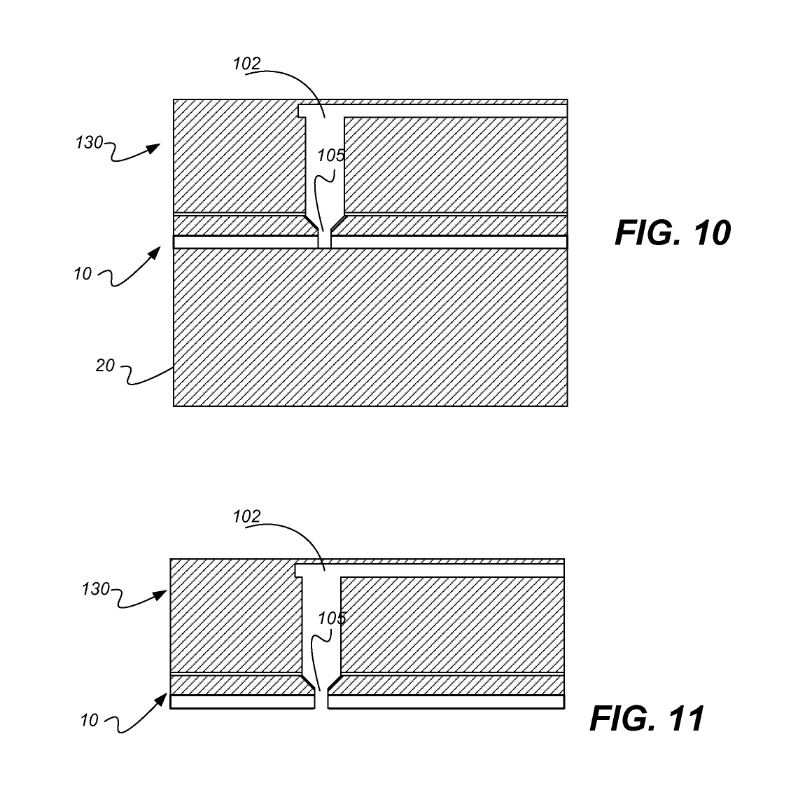

Referring to FIG. 10, a device body 130 is attached to the wafer 10, or nozzle plate, formed according to the method described herein. A flow path 102 in the device layer 130 is aligned with the nozzle 105. The walls of the fluid path 102 can intersect with the walls of the recess 77. The handle layer 20, and optionally the buried oxide layer 30, can then be removed (see FIG. 11).

In some implementations, the process described herein can be used to create short, precisely controlled rectangular straight bore nozzles in a buried oxide layer. In this implementation, the KOH process can be run until it bottoms on a buried oxide layer, the sidewalls can be protected with thermal oxide, and the buried oxide can be etched using the dry etch. After bonding the nozzle plate, the silicon handle is removed, but the buried oxide layer left in place. The straight bore length can thus be precisely controlled by the buried oxide thickness.

When nozzles having a recessed portion that leads to an outlet passage are formed where the taper is etched from one side of the substrate and the outlet is etched from the opposite side, it can be difficult to etch the outlet so that it is aligned with the tapered recess. The problem can be exacerbated by stress in the SOI wafer or stretching or compression that can be caused in the nozzle plate layer by attaching the SOI wafer to the device body. It can be very difficult to apply a mask and locally align each aperture with a tapered inlet. That is, if the SOI wafer is distorted at all, it may be possible to align a mask with some of the apertures on a substrate, but other apertures can be out of alignment. Ideally, all of the apertures across the substrate could be aligned with their respective tapered portions. Etching both the recessed portion and the outlet passage using the same mask can eliminate this problem. Moreover, using oxide to protect the sides of the recessed portion before etching the outlet passage can allow for self-alignment of the outlet passage with the recessed portion. Finally, because this method completes the nozzle etching prior to bonding the nozzle plate to the device body, if there are any defects caused by etching the nozzle plate, only the nozzle plate needs to be discarded, rather than the nozzle plate and the device body.

A number of implementations have been described. Nevertheless, it will be understood that various modifications may be made without departing from the spirit and scope of the ideas expressed herein. Accordingly, other implementations are within the scope of the following claims.

What is claimed is:

1. A method of forming a nozzle plate of a fluid ejection device, comprising:
performing a first etch from a first side of a wafer, the first etch performed on a first surface of a layer of the wafer, to form a tapered region having a floor parallel to the first surface and a tapered wall between the floor and the first surface;
forming an oxide layer in the tapered region such that a depth of the oxide layer on the tapered wall is greater than a depth of the oxide layer on the floor, wherein the depth of the oxide layer on the tapered wall and on the floor is measured in a direction perpendicular to the first surface;
performing a second etch from the first side to remove the oxide layer from the floor and to remove a first portion of the oxide layer from the tapered wall, wherein the second etch leaves a second portion of the oxide layer on the tapered wall; and
performing a third etch from the first side to form an outlet passage having a straight wall perpendicular to the first surface, the outlet passage aligned with the tapered region, the straight wall intersecting a bottom edge of the tapered wall.

2. The method of claim 1, wherein the layer is a single crystal material.

3. The method of claim 2, wherein the tapered wall is along a {111} plane and the floor is along a {100} plane.

4. The method of claim 2, wherein the single crystal material is silicon.

5. The method of claim 1, wherein the depth of the oxide on the tapered wall is greater than about 7500 Å, and wherein the depth of the oxide on the floor is less than about 5500 Å.

6. The method of claim 1, wherein growing an oxide layer in the tapered region further comprises growing the oxide layer such that a thickness of the oxide layer on the tapered wall is greater than a thickness of the oxide layer on the floor.

7. The method of claim 6, wherein the thickness of the grown thermal oxide layer on the tapered wall is greater than about 5500 Å, and wherein the thickness of the grown thermal oxide layer on the floor is less than about 5500 Å.

8. The method of claim 6, wherein forming the oxide layer comprises growing the oxide using thermal oxidation.

9. The method of claim 1, wherein forming the oxide layer comprises depositing the oxide using chemical vapor deposition.

10. The method of claim 1, wherein performing the first etch comprises performing an anisotropic wet etch.

11. The method of claim 1, wherein performing the second etch comprises performing a dry etch.

12. The method of claim 1, wherein performing the third etch comprises performing an anisotropic dry etch.

13. The method of claim 1, wherein performing the third etch includes etching to a buried oxide layer.

14. The method of claim 1, wherein performing the third etch includes etching to a highly doped layer.

15. The method of claim 1, further comprising removing the second portion of the oxide layer on the tapered wall after performing the third etch.

16. A fluid ejection device, comprising:
a substrate having a flow path formed therein; and
a nozzle plate having a nozzle formed therein, the nozzle comprising:
a tapered region having a tapered wall, the tapered wall connected to a wall defining the flow path;
an outlet passage having a straight wall, the straight wall connected to the tapered wall; and
an oxide layer coating the tapered wall, but not the straight wall.

17. The fluid ejection device of claim 16, wherein the outlet passage has a square cross-section.

18. The fluid ejection device of claim 16, wherein the outlet passage has a rectangular cross-section.

19. The fluid ejection device of claim 16, wherein the substrate comprises silicon.

20. The fluid ejection device of claim 16, wherein the oxide comprises silicon oxide.

21. The fluid ejection device of claim 16, wherein the oxide layer has a thickness that varies by less than 5%.

22. The fluid ejection device of claim 16, wherein the oxide layer has a thickness of less than 3,000 Å.
